(19) United States
(12) Patent Application Publication
(10) Pub. No.: US 2016/0293269 A1
(43) Pub. Date: Oct. 6, 2016

(54) SHIFT REGISTER AND DISPLAY DEVICE HAVING THE SAME

(71) Applicant: SAMSUNG DISPLAY CO., LTD., Yongin-si (KR)

(72) Inventors: Jae Keun Lim, Yongin-si (KR); Jong Hee Kim, Yongin-si (KR); Ji Sun Kim, Yongin-si (KR); Young Wan Seo, Yongin-si (KR); Chong Chul Chai, Yongin-si (KR)

(21) Appl. No.: 14/970,350

(22) Filed: Dec. 15, 2015

(30) Foreign Application Priority Data
Mar. 30, 2015 (KR) 10-2015-0044488

(51) Int. Cl. G11C 19/28; G09G 5/00

(52) U.S. Cl. CPC G11C 19/28; G09G 5/003; G09G 2300/0871; G09G 2310/0289; G09G 2310/08

(57) ABSTRACT

There is provided a shift register including a plurality of stages sequentially coupled to an input terminal configured to receive a start pulse, wherein each of the plurality of stages includes a first transistor coupled between a first clock input terminal and an output terminal and having a first gate electrode coupled to a first node, a second transistor coupled between the output terminal and a power input terminal and having a second gate electrode coupled to a second clock input terminal, and a third transistor coupled between the first node and a first input terminal configured to receive the start pulse or an output signal of a previous stage of the stages, the third transistor having a third gate electrode coupled to the second clock input terminal.

### CROSS-REFERENCE TO RELATED APPLICATION

This application claims priority to and the benefit of Korean Patent Application No. 10-2015-0044488, filed on Mar. 30, 2015, in the Korean Intellectual Property Office, the entire content of which is incorporated herein by reference.

### BACKGROUND

1. Field

Embodiments relate to a shift register and a display device having the same.

2. Description of the Related Art

A display device may include a plurality of pixels formed at cross sections of scan lines and data lines and a scan driver and a data driver for driving the pixels.

The scan driver may receive a scan control signal including a start pulse and a clock signal, and in response, output scan signals sequentially to the scan lines. To this end, the scan driver may include a shift register.

The scan driver may be integrated onto a panel along with scan lines, data lines and pixel circuits. When the scan driver is integrated onto the panel, there is no need to manufacture an additional chip for scan driving, and therefore, the manufacture cost may be reduced.

### SUMMARY

Aspects of embodiments of the present invention are directed toward a shift register provided on a scan driver and a display device having the same

Aspects of embodiments of the present invention are directed toward a shift register including a plurality of stages dependently (operably) coupled to an input terminal of a start pulse.

According to some embodiments of the present invention, there is provided a shift register including: a plurality of stages sequentially coupled to an input terminal configured to receive a start pulse, wherein each of the plurality of stages includes: a first transistor coupled between a first clock input terminal and an output terminal and having a first gate electrode coupled to a first node; a second transistor coupled between the output terminal and a power input terminal and having a second gate electrode coupled to a second clock input terminal; and a third transistor coupled between the first node and a first input terminal configured to receive the start pulse or an output signal of a previous stage of the stages , the third transistor having a third gate electrode coupled to the second clock input terminal.

In an embodiment, a first clock signal input into the first clock input terminal and a second clock signal input into the second clock input terminal are out of phase by a half clock cycle.

In an embodiment, each of the plurality of stages further includes a first capacitor coupled between the first node and the output terminal.

In an embodiment, each of the plurality of stages further includes a second capacitor coupled between the first node and the second clock input terminal.

In an embodiment, a capacitance of the second capacitor is less than that of the first capacitor.

In an embodiment, odd stages of the plurality of stages are configured to receive a first clock signal and a second clock signal at the first clock input terminal and the second clock input terminal, respectively, and even stages of the plurality of stages are configured to receive the second clock signal and the first Clock signal at the first clock input terminal and the second clock input terminal, respectively.

In an embodiment, the first transistor, the second transistor, and the third transistor are implemented with a same kind of transistor.

In an embodiment, each of the first transistor, the second transistor, and the third transistor include an amorphous transistor, an oxide transistor or a low temperature polysilicon transistor.

According to some embodiments of the present invention, there is provided a display device including: a plurality of pixels at cross sections of scan lines and data lines; a scan driver including a shift register configured to supply scan signals to the scan lines; and a data driver configured to supply data signals to the data lines, wherein the shift register includes a plurality of stages sequentially coupled to an input terminal configured to receive a start pulse, and wherein each of the plurality of stages includes: a first transistor coupled between a first clock input terminal and an output terminal and having a first gate electrode coupled to a first node; a second transistor coupled between the output terminal and a power input terminal and having a second gate electrode coupled to a second clock input terminal; and a third transistor coupled between the first node and a first input terminal configured to receive the start pulse or an output signal of a previous stage of the stages, the third transistor having a third gate electrode coupled to the second clock input terminal.

In an embodiment, a first clock signal input into the first clock input terminal and a second clock signal input into the second clock input terminal are out of phase by a half clock cycle.

In an embodiment, each of the plurality of stages further includes a first capacitor coupled between the first node and the output terminal.

In an embodiment, each of the plurality of stages further includes a second capacitor coupled between the first node and the second clock input terminal.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. Like reference numerals refer to like elements throughout.

FIG. 1 is a block diagram schematically illustrating a display device according to an embodiment of the present invention.

FIG. 2 is a block diagram illustrating a shift register according to an embodiment of the present invention.

FIG. 3 is a circuit diagram illustrating an example of a stage provided in the shift register shown in FIG. 2.

FIG. 4 is a wave diagram of an input/output signal of the stage shown in FIG. 3.

FIG. 5 is a wave diagram illustrating an output waveform of a shift register as envisioned according to an embodiment of the present invention.

### DETAILED DESCRIPTION

In the following detailed description, only certain exemplary embodiments of the present invention have been shown and described, simply by way of illustration.

As those skilled in the art would realize, the described embodiments may be modified in various different ways, all without departing from the spirit or scope of the present invention. Accordingly, the drawings and description are to be regarded as illustrative in nature and not restrictive.

The terminology used herein is for the purpose of describing particular embodiments only and is not intended to be limiting of the invention. Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

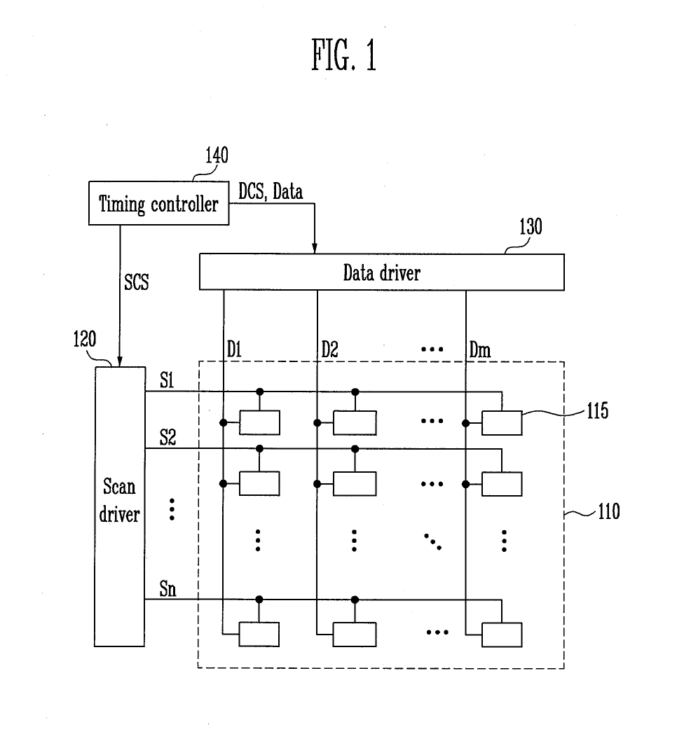

FIG. 1 is a block diagram schematically illustrating a display device according to an embodiment of the present invention.

Referring to FIG. 1, a display device according to an embodiment may include a pixel portion 110 including a plurality of pixels 115, a scan driver 120 and a data driver 130 for driving the pixels 115, and a timing controller 140 for driving the scan driver 120 and the data driver 130.

The pixel portion 110 may include a plurality of pixels 115 located at cross sections (regions) of scan lines S1 to Sn (where n is a natural number) and data lines D1 to Dm (where m is a natural number).

The plurality of pixels 115 may be selected when scan signal is supplied from a scan line S of a corresponding horizontal line and receive a data signal from a corresponding data line D. Each of the plurality of pixels 115 that received a data signal may emit light having a brightness corresponding to the data signal. As a result, images may be displayed from the pixel portion 110. The pixels 115 may be implemented in various suitable manners, for example, but without limitation thereto, implemented with pixels of a liquid crystal display device or pixels of an organic light emitting display device.

The scan driver 120 may receive a scan control signal SCS, which includes a start pulse and a clock signal, from a timing controller 140 and may sequentially supply scan signals to the scan lines S1 to Sn in response.

To this end, the scan driver 120 may generate scan signals sequentially in response to the scan control signals SCS and include a shift register for outputting sequentially the scan signals to the scan lines S1 to Sn.

The data driver 130 may receive a data control signal DCS and an input data Data from the timing controller 140 and generate data signals in response. The data signals generated from the data driver 130 may be supplied to the data lines D1 to Dm.

The timing controller 140 may generate scan control signal SCS and data control signal DCS in response to synchronization signals supplied from an external device. The scan control signal SCS generated from the timing controller 140 may be supplied to the scan driver 120, and the data control signal DCS may be supplied to the data driver 130. The timing controller 150 may supply the input data Data supplied from an external device to the data driver 130.

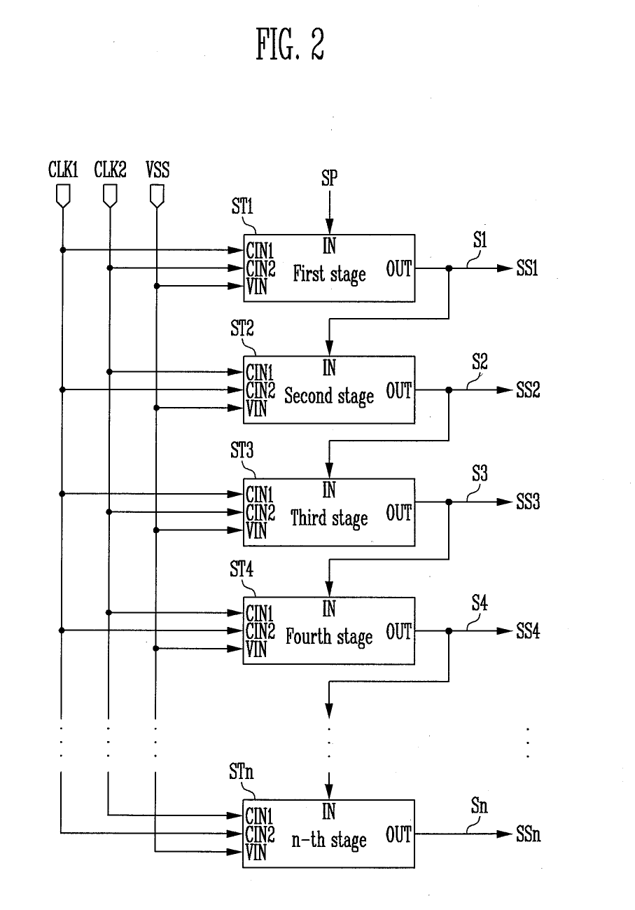

FIG. 2 is a block diagram illustrating a shift register according to an embodiment of the present invention. The shift register in FIG. 2 may be provided in the scan driver of a display device and the like, and may be provided in, for example but without limitation thereto, the scan driver 120 shown in FIG. 1.

Referring to FIG. 2, the shift register according to an embodiment may include a plurality of stages ST1 to STn dependently coupling to an input terminal of a start pulse SP.

For example, but without limitation thereto, the start pulse SP may be input into a first input terminal IN of a first stage ST1, and an output signal SS of a previous stage ST may be input into a first input terminal IN of second to n-th stages ST2 to STn.

Each of the stages ST may phase delay for a preset amount of time and output the start pulse SP input into the first input terminal IN or the output signal SS of the previous stage.

For example, but without limitation thereto, the first stage ST1 may output the start pulse SP input into the first input terminal IN by phase delaying it by one clock cycle. In addition, the second to n-th stages ST2 to STn may output the output signal SS of the previous stage ST input into the first input terminal IN by phase delaying it by one clock cycle.

To this end, the stages ST may further receive first and second clock signals CLK1 and CLK2 and a power voltage VSS, along with the start pulse SP or the output signal SS of the previous stage ST and be driven.

In an embodiment, the first and second clock signals CLK1 and CLK2 may be set to clock signals with reversed phases (e.g., may be out of phase by half of a clock cycle). That is, the second clock signal CLK2 may be a reverse signal CLK1B of the first clock signal CLK1.

The first and second clock signals CLK1 and CLK2 may be alternately supplied to the first and second clock input terminals CIN1 and CIN2 in each stage ST.

For example, but without limitation thereto, odd stages ST₂ₖ₋₁ (where k is a natural number) may receive the first and second clock signals CLK1 and CLK2 in first and second clock input terminals CIN1 and CIN2, respectively, and even stages ST₂k (where k is a natural number) may receive the second and first clock signals CLK2 and CLK1 in the first and second clock input terminals CIN1 and CIN2, respectively.

As a result, output signals SS1 to SSn that are sequentially phase delayed from each of the stages ST1 to STn may be realized. The generated output signals SS1 to SSn may be supplied to the scan lines S1 to Sn, respectively, thereby becoming scan signals for selecting pixel lines.

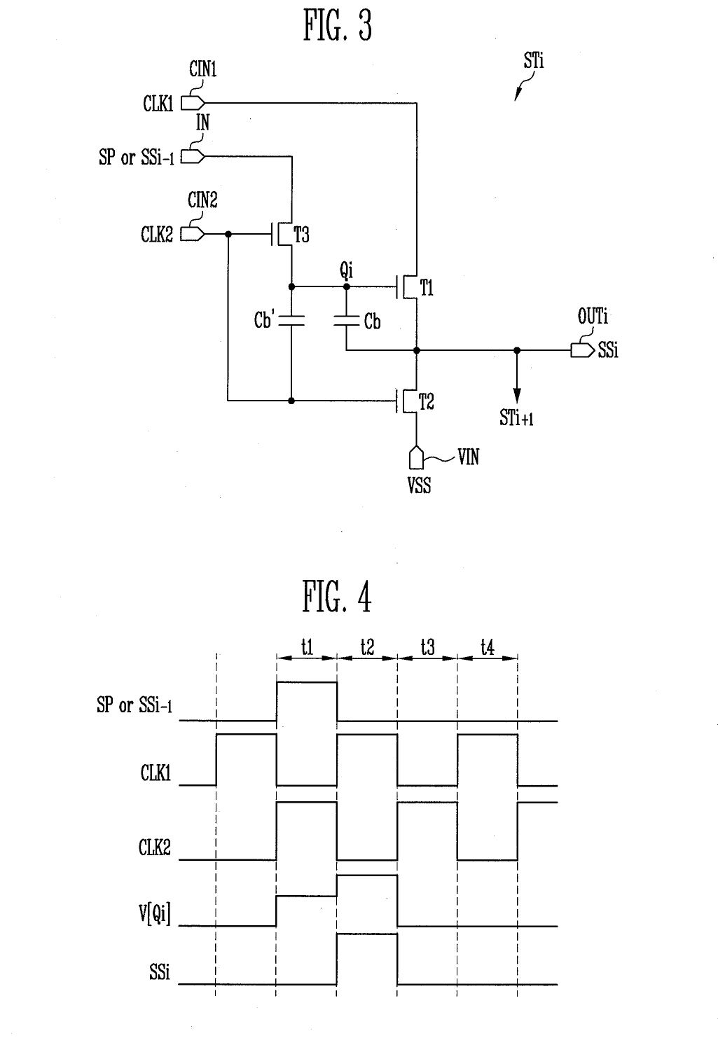

FIG. 3 is a circuit diagram illustrating an example of a stage provided in the shift register shown in FIG. 2. For convenience of illustration, i-th stage (where i is a natural number) is shown in FIG. 3.

Referring to FIG. 3, each of the stages STi may include a first transistor T1, a second transistor T2, a third transistor T3, a first capacitor Cb and a second capacitor Cb'.

The first transistor T1 may be coupled between a first clock input terminal CIN1 and an output terminal OUTi. A gate electrode of the first transistor T1 may be coupled to a first node Qi. The first clock signal CLK1 or the second clock signal CLK2 may be input into the first clock input terminal CIN1. However, for convenience of illustration, the first clock signal CLK1 will be described as being input into the first clock input terminal CIN1, and the second clock signal CLK2 will be described as being input into the second clock input terminal CIN2.

The first transistor T1 may be turned on or turned off in response to a voltage of the first node Qi. When the first transistor T1 is turned on, the voltage of the first clock signal CLK1 input into the first clock input terminal CIN1 may be transferred to an output terminal OUTi via the first transistor T1.

A second transistor T2 may be coupled between the output terminal OUTi and a power input terminal VIN. A gate electrode of the second transistor T2 may be coupled to the second clock input terminal CIN2. Here, a power voltage VSS may be input into the power input terminal VIN, and a second clock signal CLK2 may be input into the second clock input terminal CIN2.

The power voltage VSS may be set to a voltage of a voltage level that is opposite to a voltage level of a scan signal SSi output to the output terminal OUTi. For example, but without limitation thereto, when a high level scan signal SSi is sequentially supplied to the output terminal OUTi of each stage, the power voltage VSS may be set to a low level voltage. For example, but without limitation thereto, the power voltage VSS may be set to a voltage that is the same as or similar to a low level voltage of the first clock signal CLK1, the second clock signal CLK2 and/or a start pulse SP.

The second clock signal CLK2 may be a clock signal having a waveform that is opposite to a clock signal input into the first clock input terminal CIN1, and may be set to, for example, but without limitation thereto, a reverse signal CLK1 B of the first clock signal CLK1 (i.e., the first and second clock signals CLK1 and CLK2 may be out of phase by half a clock cycle). The first clock signal CLK1 and the second clock signal CLK2 may have different reversed phases. However, ascending or descending edges of the first and second clock signals CLK1 and CLK2 may overlap each other, or, there may be a preset gap (or preset delay) between the ascending or descending edges of the first and second clock signals CLK1 and CLK2.

The second transistor T2 may be turned on or turned off in response to the voltage of the second clock signal CLK2. When the second transistor T2 is turned on, the power voltage VSS input into the power input terminal VIN may be transferred to the output terminal OUTi via the second transistor T2.

A third transistor T3 may be coupled between the first input terminal IN and the first node Qi. A gate electrode of the third transistor T3 may be coupled to the second clock input terminal CIN2. The start pulse SP or an output signal SSi-1 of the previous stage may be input into the first input terminal IN.

The third transistor T3 may be turned on or turned off in response to a voltage of the second clock signal CLK2. When the third transistor T3 is turned on, the start pulse SP or the output signal SSi-1 of the previous stage input into the first input terminal IN may be transferred to the first node Qi.

The first transistor T1, the second transistor T2 and the third transistor T3 may be implemented with the same type (kind) of transistor. For example, but without limitation thereto, the first transistor T1, the second transistor T2 and the third transistor T3 may all be implemented with an amorphous silicon a-Si transistor, or with oxide transistor or low temperature polysilicon LTPS transistor.

Likewise, when the first to third transistors T1, T2 and T3 are implemented with the same type of transistors, the manufacturing method may be simplified. Particularly, when the first to third transistors T1, T2 and T3 are implemented with the same type of transistors as the transistors provided in the pixel circuit, process efficiency may be increased and manufacturing cost may be reduced in the event of integrating the scan driver on the panel, and the like.

A first capacitor Cb may be coupled between the first node Qi and the output terminal OUTi. The first capacitor Cb may cause coupling between the first node Qi and the output terminal OUTi, and may increase charge speed of the first node Qi and stabilize voltage of the output terminal OUTi.

A second capacitor Cb' may be coupled between the first node Qi and the second clock input terminal CIN2. The second capacitor Cb' may cause coupling between the first node Qi and the second clock input terminal CIN2, thereby stabilizing the voltage of the first node Qi. As a result, the voltage of the output terminal OUTi may be stabilized. In an example, the second capacitor Cb' may drop the voltage of the first node Qi to a voltage that is lower than, for example, but without limitation thereto, the voltage of the power voltage VSS after the scan signal is output to the output terminal OUTi, thereby stably maintaining the turn off state of the first transistor Ti.

In order to obtain stable output properties, however, a capacity of the second capacitor Cb′ may be set to be smaller than a capacity of the first capacitor Cb.

The output terminal OUTi of an i-th stage STi shown in FIG. 3 may be coupled to the first input terminal IN of the (i+1)-th stage STᵢ₊ᵢ, which is the next stage. Accordingly, the (i+1)-th stage STᵢ₊₁ may output an output signal SSᵢ₊ᵢ which is a phase delayed form of the output signal SSi of the i-th stage STi.

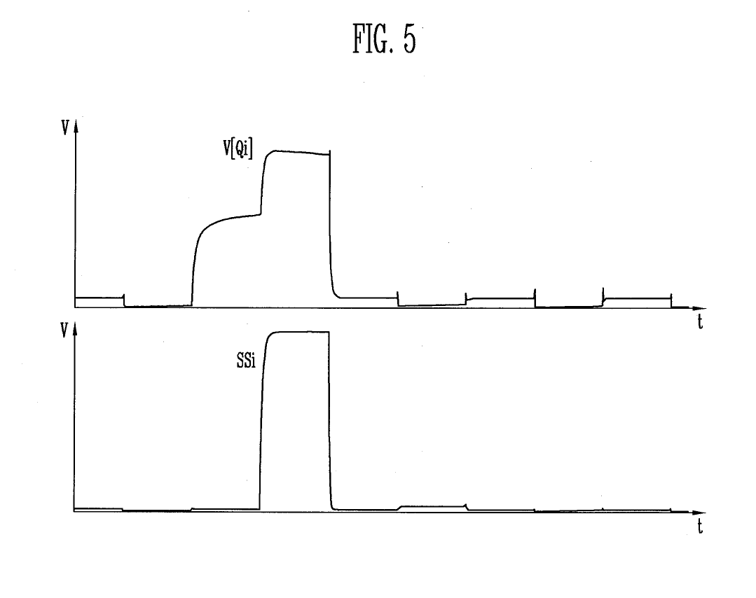

FIG. 4 is a wave diagram of an input/output signal of the stage shown in FIG. 3. Hereinafter, the waveform diagram shown in FIG. 4 may be linked with the stage circuit shown in FIG. 3 to describe in more detail the operations of the stage shown in FIG. 3.

For convenience of illustration, ascending edges and descending edges of the first and second clock signals CLK1 and CLK2 are shown as overlapping each other in FIG. 4. However, there may exist a gap (or preset delay) between them. In addition, in FIG. 4, for convenience of illustration, factors such as signal delay and the like are not considered.

Referring to FIG. 4, a high level second clock signal CLK2 may be input in a state in which a high level start pulse SP or an output signal SS;_{—i} of the previous stage is being input during a first period t1. Second and third transistors T2 and T3 may be turned on in response to the high level second clock signal CLK2.

When the second transistor T2 is turned on, the output terminal OUTi may be coupled to the low level power voltage VSS. Accordingly, the output signal SSi may stably maintain the low level voltage.

When the third transistor T3 is turned on, the start pulse SP or the high level voltage of the output signal SSᵢ₋₁ of the previous stage input into the first input terminal

IN may be transferred to the first node Qi. Accordingly, as the first node Qi is charged with a high level voltage, a voltage V[Qi] of the first node may increase. The first period t1 may be a pre-charge period.

When the first node Qi is charged with a high level voltage during the first period t1 as such, the first transistor T1 may be turned on, and a voltage of the first clock signal CLK1 may be transferred to the output terminal OUTi.

Thereafter, when the voltage of the second clock signal CLK2 is transitioned to low level during a second period t2, the second and third transistors T2 and T3 may be turned off.

And when a high level first clock signal CLK1 I input during the second period t2, the high level voltage of the first clock signal CLK1 may be transferred to the output terminal OUTi through the turned on first transistor Ti.

When the voltage of the output terminal OUTi increases to high level, a boot-strap of the first node Qi may be caused by the coupling of the first capacitor Cb, and thus the voltage V[Qi] of the first node Qi may additionally increase. That is, the second period t2 may be a boot-strapping period.

If the voltage V[Qi] of the first node Qi is additionally increased, the first transistor T1 may be sufficiently turned on and charge, in high speed, the output terminal OUTi to a high level voltage.

Accordingly, the high level output signal SSi, that is, a scan signal, may be output during the second period t2. While the scan signal SSi may be output to an i-th scan line coupled to the output terminal OUTi of the i-th stage STi, it may be input into the first input terminal IN of the (i+1)-th stage STᵢ₊ᵢ and drive the (i+1)-th stage STᵢ₊₁.

Thereafter, when the voltage of the second clock signal CLK2 is transitioned to high level during a third period t3, the second and third transistors T2 and T3 may be turned on.

When the second transistor T2 is turned on, the low level voltage of the power voltage VSS may be transferred to the output terminal OUTi. Accordingly, the voltage of the output signal SSi may descend to low level and the output terminal OUTi may be stabilized.

When the third transistor T3 is turned on, the start pulse SP input into the first input terminal IN or the low level voltage of the output signal SSᵢ₋₁ of the previous stage may be transferred to the first node Qi. Accordingly, the voltage V[Qi] of the first node Qi may descend to low level, and the first node Qi may be stabilized. In addition, as the voltage V[Qi] of the first node Qi drops to low level, the first transistor T1 may be turned off. The third period t3 may be a hold period Hold.

During a fourth period t4, that is, a period following the third period t3, when the voltage level of the second clock signal CLK2 is transitioned to low level, the second and third transistors T2 and T3 may be turned off.

Here, the voltage of the first node Qi may descend to a lower voltage than the previous low level voltage (e.g., VSS voltage) due to the coupling of the second capacitor Cb'. As a result, the first transistor T1 may be effectively prevented from being turned on, and leakage current may be reduced or blocked. Accordingly, voltage change (ripple) of the output signal SSi may be repressed, and the voltage of the output terminal OUTi may be stabilized.

Therefore, the i-th stage STi may maintain the low level voltage of the output signal SSi stably until the high level start pulse SP or the output signal SSi-1 of the previous stage is applied again.

The output terminal OUTi of the i-th stage STi shown in FIG. 3 may be coupled to the first input terminal IN of the (i+1)-th stage STᵢ₊1, which is the next terminal stage. Then, the (i+1)-th stage STᵢ₊ᵢ may phase delay the scan signal output from the i-th stage STi (e.g., high level output signal SSi) as much as one clock cycle and output it.

Through the above-described process, the shift register according to an embodiment may sequentially phase delay the start pulse SP and output it and sequentially supply scan signals SS1 to SSn to scan lines S1 to Sn.

The stage STi shown in FIG. 3 as described above may be simply configured using only three transistors T1, T2 and T3 and two capacitors Cb and Cb′, and may output in a stable manner by effectively reducing ripple of the output signal SSi.

According to an embodiment, because each stage is configured with a reduced or minimum number of circuit devices, the circuit configuration of the shift register is simplified, yet the output of the shift register is stabilized.

In addition, according to an embodiment, because only the output terminal OUTi of the i-th stage STi may be coupled to the first input terminal IN of the (i+1)-th stage STᵢ₊₁, the coupling structure between the stages ST may be simplified.

As a result, while the circuit configuration of the scan driver to which the shift register is applied is simplified, high reliability may be provided. Likewise, when the circuit configuration of the scan driver is simplified, the scan driver may be easily integrated on the panel.

FIG. 5 is a wave diagram illustrating an output waveform of a shift register as envisioned according to an embodiment of the present invention. For convenience of illustration, only the output waveform of one stage is illustrated in FIG. 5.

Referring to FIG. 5, after a high level scan signal is output, even when the phase transition repeats itself in a cycle, it may be confirmed that the voltage V[Qi] of the first node Qi and the voltage of the output signal SSi are prevented or substantially prevented from changing.

According to an embodiment, ripple properties of the shift register may be improved, and a scan driver with high reliability may be provided.

By way of summation and review, a scan driver may be integrated onto a panel along with scan lines, data lines and pixel circuits. When the scan driver is integrated onto the panel, there is no need to manufacture an additional chip for scan driving, and therefore, the manufacture cost may be reduced.

However, in order to easily integrate a scan driver onto a panel, it is desirable that circuit configuration of the scan driver be simplified while reliability is secured.

According to an embodiment of the present invention, a shift register and a display device having the same may be configured with a reduced or minimum number of circuit devices and be highly reliable. When circuit configuration of the scan driver is simplified as such, the scan driver may be easily integrated onto a panel.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent to” another element or layer, it can be directly on, connected to, coupled to, or adjacent to the other element or layer, or one or more intervening elements or layers may be present. When an element or layer is referred to as being “directly on,” “directly connected to”, “directly coupled to”, or “immediately adjacent to” another element or layer, there are no intervening elements or layers present.

The display device, the shift register, and/or any other relevant devices or components according to embodiments of the present invention described herein may be implemented utilizing any suitable hardware, firmware (e.g. an application-specific integrated circuit), software, or a suitable combination of software, firmware, and hardware. For example, the various components of the display device and the shift register may be formed on one integrated circuit (IC) chip or on separate IC chips. Further, the various components of the display device and the shift register may be implemented on a flexible printed circuit film, a tape carrier package (TCP), a printed circuit board (PCB), or formed on a same substrate. Further, the various components of the display device and the shift register may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the exemplary embodiments of the present invention.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various suitable changes in form and details may be made without departing from the spirit and scope of the present invention as set forth in the following claims, and equivalents thereof.

What is claimed is:

1. A shift register comprising:
a plurality of stages sequentially coupled to an input terminal configured to receive a start pulse,
wherein each of the plurality of stages comprises:
a first transistor coupled between a first clock input terminal and an output terminal and having a first gate electrode coupled to a first node;
a second transistor coupled between the output terminal and a power input terminal and having a second gate electrode coupled to a second clock input terminal; and
a third transistor coupled between the first node and a first input terminal configured to receive the start pulse or an output signal of a previous stage of the stages, the third transistor having a third gate electrode coupled to the second clock input terminal.

2. The shift register as claimed in claim 1, wherein a first clock signal input into the first clock input terminal and a second clock signal input into the second clock input terminal are out of phase by a half clock cycle.

3. The shift register as claimed in claim 1, wherein each of the plurality of stages further comprises a first capacitor coupled between the first node and the output terminal.

4. The shift register as claimed in claim 3, wherein each of the plurality of stages further comprises a second capacitor coupled between the first node and the second clock input terminal.

5. The shift register as claimed in claim 4, wherein a capacitance of the second capacitor is less than that of the first capacitor.

6. The shift register as claimed in claim 1, wherein odd stages of the plurality of stages are configured to receive a first clock signal and a second clock signal at the first clock input terminal and the second clock input terminal, respectively, wherein even stages of the plurality of stages are configured to receive the second clock signal and the first clock signal at the first clock input terminal and the second clock input terminal, respectively.

7. The shift register as claimed in claim 1, wherein the first transistor, the second transistor, and the third transistor are implemented with a same kind of transistor.

8. The shift register as claimed in claim 7, wherein each of the first transistor, the second transistor, and the third transistor comprise an amorphous transistor, an oxide transistor or a low temperature polysilicon transistor.

9. A display device comprising:
a plurality of pixels at cross sections of scan lines and data lines;
a scan driver comprising a shift register configured to supply scan signals to the scan lines; and
a data driver configured to supply data signals to the data lines,
wherein the shift register comprises a plurality of stages sequentially coupled to an input terminal configured to receive a start pulse, and
wherein each of the plurality of stages comprises:
a first transistor coupled between a first clock input terminal and an output terminal and having a first gate electrode coupled to a first node;
a second transistor coupled between the output terminal and a power input terminal and having a second gate electrode coupled to a second clock input terminal; and
a third transistor coupled between the first node and a first input terminal configured to receive the start pulse or an output signal of a previous stage of the stages, the third transistor having a third gate electrode coupled to the second clock input terminal.

10. The display device as claimed in claim 9, wherein a first clock signal input into the first clock input terminal and a second clock signal input into the second clock input terminal are out of phase by a half clock cycle.

11. The display device as claimed in claim 9, wherein each of the plurality of stages further comprises a first capacitor coupled between the first node and the output terminal.

12. The display device as claimed in claim 9, wherein each of the plurality of stages further comprises a second capacitor coupled between the first node and the second clock input terminal.

13. The display device as claimed in claim 9,
wherein odd stages of the plurality of stages are configured to receive a first clock signal and a second clock signal at the first clock input terminal and the second clock input terminal, respectively, and
wherein even stages of the plurality of stages are configured to receive the second clock signal and the first clock signal at the first clock input terminal and the second clock input terminal, respectively.

14. The display device as claimed in claim 9, wherein the first transistor, the second transistor, and the third transistor are implemented with a same kind of transistor.

15. The shift register as claimed in claim 14, wherein each of the first transistor, the second transistor, and the third transistor comprise an amorphous transistor, an oxide transistor or a low temperature polysilicon transistor.
